(19) United States
(12) Patent Application Publication
(10) Pub. No.: US 2026/0293560 A1
(43) Pub. Date: Sep. 24, 2026

(54) SEMICONDUCTOR SUBSTRATE, SEMICONDUCTOR EPITAXIAL WAFER, AND METHOD OF MANUFACTURING SEMICONDUCTOR SUBSTRATE

(71) Applicant: Mitsubishi Electric Corporation, Tokyo (JP)

(72) Inventors: Takuyo NAKAMURA, Tokyo (JP); Kenichi HAMANO, Tokyo (JP); Takanori TANAKA, Tokyo (JP)

(73) Assignee: Mitsubishi Electric Corporation, Tokyo (JP)

(21) Appl. No.: 19/424,086

(22) Filed: Dec. 17, 2025

(30) Foreign Application Priority Data
Mar. 19, 2025 (JP) 2025-044794

(51) Int. Cl. H10P 52/40; H10P 14/20; H10W 29/00

(52) U.S. Cl. CPC H10P 52/402; H10P 14/2904; H10W 29/00

(57) ABSTRACT

An object of the present disclosure is to provide the semiconductor substrate and a semiconductor epitaxial wafer capable of achieving both measures against an epitaxial crown and prevention of breakage or cracking occurring from a terminal end portion as a start point and a method of manufacturing the semiconductor substrate. A semiconductor substrate according to the present disclosure includes: an effective region as a region in which a semiconductor chip is formed and including a first main surface; an ineffective region located on an outer surrounding of the first main surface and including a second main surface having a surface shape different from the first main surface; and an end surface processing portion located on an outer surrounding of the second main surface and included in the ineffective region, wherein a surface height of the second main surface is lower than a surface height of the first main surface.

### BACKGROUND

### Technical Field

The present disclosure relates to a semiconductor substrate, a semiconductor epitaxial wafer, and a method of manufacturing the semiconductor substrate.

### Description of the Background Art

In an epitaxial growth on the semiconductor substrate, a disturbed flow and accumulation of growth gas occurs around a terminal end portion of the semiconductor substrate due to a gap and a level difference between the terminal end portion of the semiconductor substrate and a wafer holder. At this time, a concentration of the growth gas increases and an epitaxial growth rate partially increases around the terminal end portion. A semiconductor epitaxial film is locally thickened around the terminal end portion of the semiconductor substrate by increase of this partial epitaxial growth rate, and is epitaxially grown into a crown-like shape. A part epitaxially grown into the crown-like shape is referred to as an epitaxial crown hereinafter.

After a front surface structure of the semiconductor substrate is formed by an epitaxial growth, a back surface is ground and polished to form a back surface structure. Resin is applied to the front surface and hardened to protect the front surface structure immediately before grinding and polishing the back surface. Then, the hardened resin on the front surface is ground to be flat so that stress is not concentrated to a part of the front surface in forming the back surface structure. At this time, when the epitaxial crown is high, a turning tool has contact with the epitaxial crown in grinding the resin and breakage or cracking of the semiconductor substrate occurs in some cases. Accordingly, it is necessary to take measures against the epitaxial crown in creating the semiconductor substrate.

Disclosed conventionally is the semiconductor substrate provided with an inclined part in a terminal end portion (for example, refer to Japanese Patent Application Laid-Open No. 2002-83753).

### SUMMARY

Japanese Patent Application Laid-Open No. 2002-83753 focuses on a fact that the epitaxial crown is caused by a patterning defect of a resist mask, and includes the inclined part in the terminal end portion of the semiconductor substrate to prevent this patterning defect.

In the meanwhile, the terminal end portion of the semiconductor substrate often serves as a start point of breakage or cracking of the semiconductor substrate. Thus, it is preferable to appropriately design the semiconductor substrate to prevent such breakage or cracking. However, there is room for improvement in Japanese Patent Application Laid-Open No. 2002-83753 by reason that it does not have a structure of preventing the breakage or the cracking of the semiconductor substrate.

An object of the present disclosure is to provide the semiconductor substrate and semiconductor epitaxial wafer capable of achieving both measures against an epitaxial crown and prevention of breakage or cracking occurring from a terminal end portion as a start point and a method of manufacturing the semiconductor substrate.

A semiconductor substrate according to the present disclosure includes: an effective region as a region in which a semiconductor chip is formed and including a first main surface; an ineffective region located on an outer surrounding of the first main surface and including a second main surface having a surface shape different from the first main surface; and an end surface processing portion located on an outer surrounding of the second main surface and included in the ineffective region, wherein a surface height of the second main surface is lower than a surface height of the first main surface.

According to the present disclosure, achievable are both measures against an epitaxial crown and prevention of breakage or cracking occurring from a terminal end portion as a start point.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a semiconductor substrate according to an embodiment 1.

FIG. 2 is a plan view illustrating a configuration of the semiconductor substrate according to the embodiment 1.

FIG. 3 is a cross-sectional view illustrating an example of a configuration of a semiconductor substrate according to an embodiment 2.

FIG. 4 is a cross-sectional view illustrating an example of a configuration of the semiconductor substrate according to the embodiment 2.

FIG. 5 is a cross-sectional view illustrating an example of a configuration of the semiconductor substrate according to the embodiment 2.

FIG. 6 is a cross-sectional view illustrating a configuration of a semiconductor substrate according to an embodiment 3.

FIG. 7 is a cross-sectional view illustrating a configuration of a semiconductor epitaxial wafer according to an embodiment 4.

FIG. 8 is a cross-sectional view illustrating a configuration of a semiconductor epitaxial wafer according to an embodiment 5.

FIG. 9 is a flow chart illustrating a manufacturing process of a semiconductor substrate according to an embodiment 6.

### DESCRIPTION OF THE PREFERRED EMBODIMENTS

### Embodiment 1

Although an SiC substrate as a semiconductor substrate is described as an example in the present disclosure, the semiconductor substrate may be an Si substrate. However, since an epitaxial growth rate is increased more easily in a terminal end portion of the SiC substrate than in a terminal end portion of the Si substrate, an epitaxial crown is formed more easily in the terminal end portion of the SiC substrate. The SiC substrate described hereinafter is synonymous with an SiC wafer.

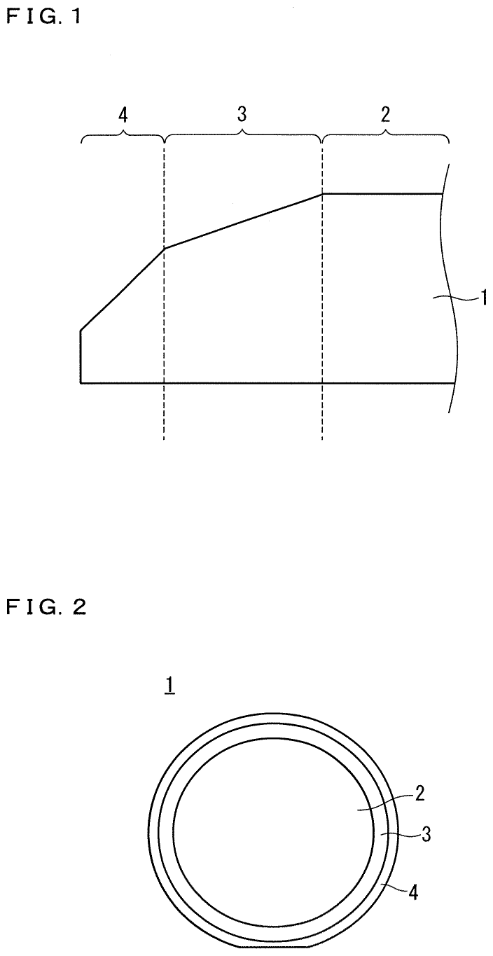

FIG. 1 is a cross-sectional view illustrating a configuration of an SiC substrate 1 according to an embodiment 1. FIG. 1 illustrates a part including a terminal end portion of the SiC substrate 1. FIG. 2 is a plan view illustrating a configuration of the SiC substrate 1. In an example in FIG. 2, an orientation flat is formed. However, a notch may be formed in place of the orientation flat. A structure (a first main surface 2, a second main surface 3, and an end surface processing portion 4 described hereinafter) according to the present disclosure can also be applied to a portion of the orientation flat or the notch.

The SiC substrate 1 includes the first main surface 2, the second main surface 2, and the end surface processing portion 4. Each of the first main surface 2, the second main surface 3, and the end surface processing portion 4 is a part of a front surface of the SiC substrate 1. An effective region includes the first main surface 2, and an ineffective region includes the second main surface 3 and the end surface processing portion 4. Herein, the effective region is a region in which a semiconductor chip (a semiconductor chip including SiC) is formed, and the ineffective region is a region in which the semiconductor chip is not formed.

The first main surface 2 is a surface in a horizontal direction in the front surface of the SiC substrate 1.

The second main surface 3 is located on an outer surrounding of the first main surface 2. The second main surface 3 is inclined from a boundary with the first main surface 2 toward the terminal end portion. That is to say, the second main surface 3 has a surface shape different from the first main surface 2. A surface height of the second main surface 3 is lower than that of the first main surface 2. Herein, the surface height of the first main surface 2 corresponds to a length from a back surface of the SiC substrate 1 to the front surface (the first main surface 2) thereof. In the similar manner, the surface height of the second main surface 3 corresponds to a length from the back surface of the SiC substrate 1 to the front surface (the second main surface 3) thereof.

The end surface processing portion 4 corresponds to a bevel, and is located on an outer surrounding of the second main surface 3.

### Effect

Since the surface height of the second main surface 3 is lower than that of the first main surface 2, a flow of growth gas is improved, and a disturbed flow and accumulation of growth gas is reduced in the epitaxial growth. Accordingly, the epitaxial growth rate of the semiconductor epitaxial film is uniformed, and occurrence of the epitaxial crown is suppressed. Herein, the state where the occurrence of the epitaxial crown is suppressed indicates that the epitaxial crown does not occur at all or the epitaxial crown having a low height occurs.

When resin is applied and hardened to protect the front surface structure after the epitaxial growth, and is ground, the effective region of the SiC region 1 can be uniformed. Accordingly, such a configuration does not have negative influence on a shape of the effective region of the SiC substrate 1 in forming the back surface structure.

Since the occurrence of the epitaxial crown is suppressed, reduced is a possibility that a turning tool has contact with the epitaxial crown in grinding the resin applied to protect the front surface structure. Thus, reduced is a risk of breakage or cracking of the semiconductor substrate caused by the contact.

Since the SiC substrate 1 is divided into the first main surface 2, the second main surface 3, and the end surface processing portion 4 in the configuration, each role thereof can be specialized in design. For example, the second main surface 3 can be designed as measures against the epitaxial crown, and the end surface processing portion 4 can be designed so that breakage or cracking of the SiC substrate 1 can be suppressed. In this manner, flexibility can be achieved in designing the SiC substrate 1.

In this manner, according to the embodiment 1, achievable are both measures against the epitaxial crown and prevention of breakage or cracking occurring from the terminal end portion as the start point.

### Embodiment 2

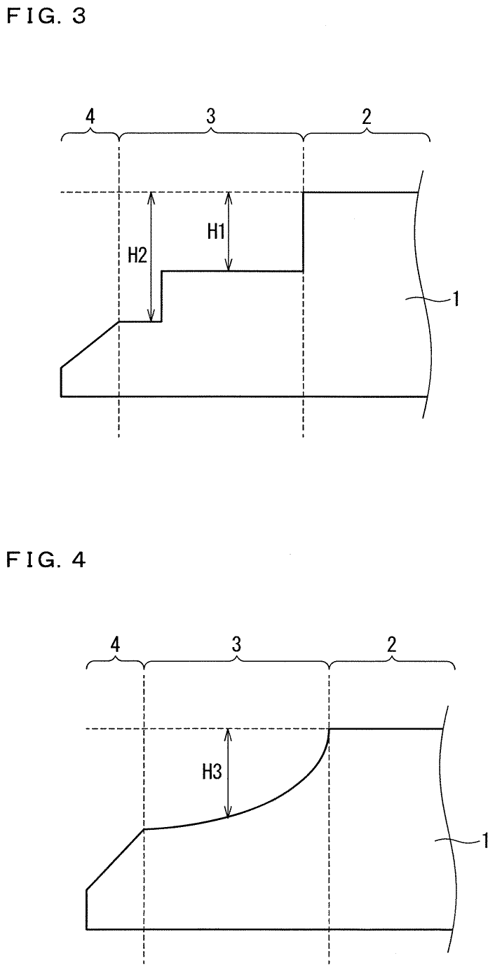

FIG. 3 is a cross-sectional view illustrating an example of a configuration of the SiC substrate 1 according to an embodiment 2. As illustrated in FIG. 3, the second main surface 3 of the SiC substrate 1 has a stepwise shape. Specifically, the second main surface 3 includes a portion of a height H1 as a difference between the surface height of the first main surface 2 and the surface height of the second main surface 3 and a portion of the height H2. The heights H1 and H2 are 4.5% to 21.5% of a thickness of the SiC substrate 1. The thickness of the SiC substrate 1 is 350 μm, and corresponds to the length from the back surface of the SiC substrate 1 to the front surface (the first main surface 2) thereof.

FIG. 4 is a cross-sectional view illustrating an example of a configuration of the SiC substrate 1 according to the embodiment 2. As illustrated in FIG. 4, the second main surface 3 of the SiC substrate 1 has a tapered shape. Specifically, the second main surface 3 includes a portion of a height H3 as a difference between the surface height of the first main surface 2 and the surface height of the second main surface 3. The height H3 is 4.5% to 21.5% of the thickness of the SiC substrate 1.

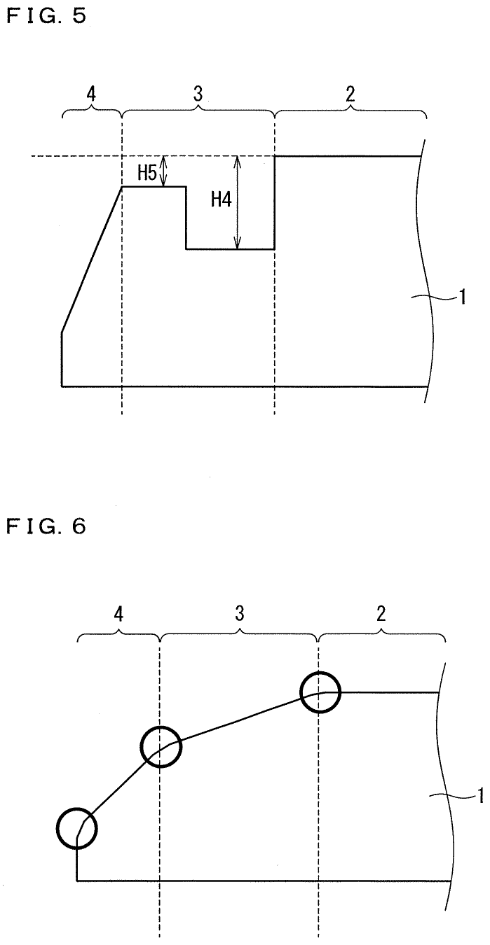

FIG. 5 is a cross-sectional view illustrating an example of a configuration of the SiC substrate 1 according to the embodiment 2. As illustrated in FIG. 5, the second main surface 3 of the SiC substrate 1 has a convex-concave shape. Specifically, the second main surface 3 includes a portion of a height H4 as a difference between the surface height of the first main surface 2 and the surface height of the second main surface 3 and a portion of a height H5. The heights H4 and H5 are 4.5% to 21.5% of the thickness of the SiC substrate 1.

### Effect

When the SiC substrate 1 is divided into the first main surface 2, the second main surface 3, and the end surface processing portion 4 in the configuration, flexibility can be achieved in designing the SiC substrate 1. Thus, an appropriate substrate design corresponding to a manufacturing process or a purpose of usage can be performed, and it is possible to deal with various manufacturing conditions.

When a semiconductor epitaxial film having a thickness of approximately 30 μm is epitaxially grown on a general SiC substrate (an SiC substrate in which the second main surface 3 is not formed), an epitaxial crown having a height of approximately 15 μm is formed on the semiconductor epitaxial film. A general epitaxial growth apparatus can continuously grow a semiconductor epitaxial film having a thickness of approximately 150 μm, and an epitaxial crown having a height of approximately 75 μm is formed on the semiconductor epitaxial film at this time. In the meanwhile, 4.5% of the thickness of the SiC substrate 1 is equal to approximately 15 μm, and 21.5% of the thickness of the SiC substrate 1 is equal to approximately 75 μm. Accordingly, when the heights H1, H2, H3, H4, and H5 are set in accordance with the thickness of the semiconductor epitaxial film, it is possible to prevent a distal end of the epitaxial crown formed on the semiconductor epitaxial film from being higher than the first main surface 2.

### Embodiment 3

FIG. 6 is a cross-sectional view illustrating a configuration of the SiC substrate 1 according to an embodiment 3. As illustrated in FIG. 6, a boundary between the first main surface 2 and the second main surface 3, a boundary between the second main surface 3 and the end surface processing portion 4, and a boundary between the end surface processing portion 4 and a side surface of the SiC substrate 1 (portions of circle marks in FIG. 6) are chamfered.

### Effect

When the boundary between the first main surface 2 and the second main surface 3, the boundary between the second main surface 3 and the end surface processing portion 4, and the boundary between the end surface processing portion 4 and the side surface of the SiC substrate 1 are chamfered, breakage or cracking of the SiC substrate 1 can be suppressed.

### Embodiment 4

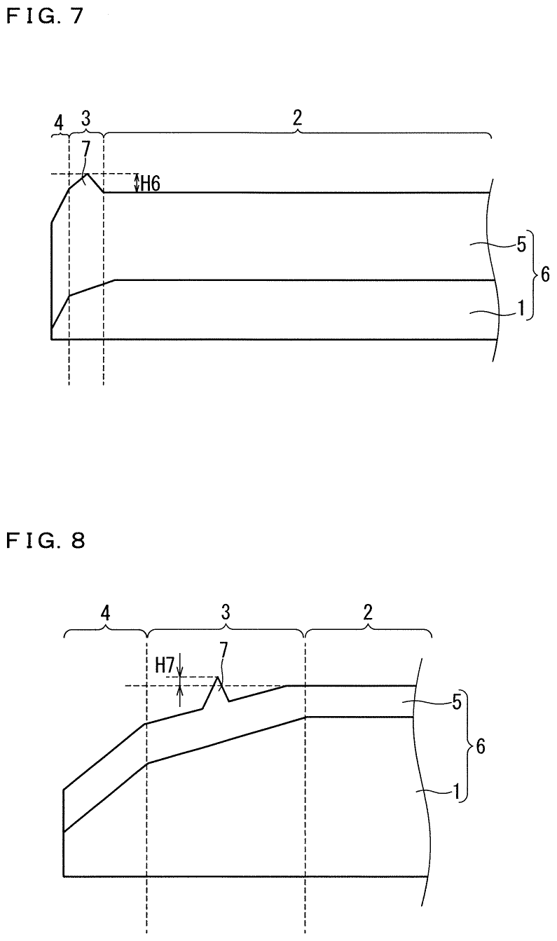

FIG. 7 is a cross-sectional view illustrating a configuration of an SiC epitaxial wafer 6 (semiconductor epitaxial wafer) according to an embodiment 4. FIG. 7 illustrates a part including a terminal end portion of the SiC epitaxial wafer 6.

The SiC epitaxial wafer 6 includes the SiC substrate 1 and an SiC epitaxial film 5. The SiC substrate 1 may be any SiC substrate 1 according to the embodiments 1 to 3.

The SiC epitaxial film 5 is formed by epitaxially growing SiC on the SiC substrate 1. A thickness of the SiC epitaxial film 5 is equal to or larger than 30 μm.

An epitaxial crown 7 (a protruding portion) is formed on a surface of the SiC epitaxial film 5 corresponding to the second main surface 3. A height H6 of the epitaxial crown 7 is 4.5% of the thickness of the SiC substrate 1. The height H6 of the epitaxial crown 7 corresponds to a length between the surface of the SiC epitaxial film 5 corresponding to the first main surface 2 and the distal end of the epitaxial crown 7.

### Effect

In the SiC substrate which does not include the second main surface 3, when the SiC epitaxial film having a thickness of approximately 30 μm is epitaxially grown on the SiC substrate, the epitaxial crown having a height of approximately 15 μm is formed on the SiC epitaxial film. In the meanwhile, since the SiC substrate 1 according to the embodiment 4 includes the second main surface 3, when the SiC epitaxial film 5 having a thickness of approximately 30 μm is epitaxially grown on the SiC substrate 1, the epitaxial crown 7 having the height H6 of 15 μm or less is formed on the SiC epitaxial film 5. That is to say, according to the embodiment 4, the height of the epitaxial crown 7 formed on the SiC epitaxial film 5 can be suppressed.

### Embodiment 5

FIG. 8 is a cross-sectional view illustrating a configuration of an SiC epitaxial wafer 6 according to an embodiment 5. FIG. 8 illustrates a part including a terminal end portion of the SiC epitaxial wafer 6.

The SiC epitaxial wafer 6 includes the SiC substrate 1 and the SiC epitaxial film 5. The SiC substrate 1 may be any SiC substrate 1 according to the embodiments 1 to 3.

The SiC epitaxial film 5 is formed by epitaxially growing SiC on the SiC substrate 1.

The epitaxial crown 7 is formed on the surface of the SiC epitaxial film 5 corresponding to the second main surface 3. A height H7 of the epitaxial crown 7 is equal to or smaller than 15 μm from the surface of the SiC epitaxial film 5 corresponding to the first main surface 2. A position of a bottom portion of the epitaxial crown 7 is lower than the surface of the SiC epitaxial film 5 corresponding to the first main surface 2. The height H7 of the epitaxial crown 7 corresponds to the length between the surface of the SiC epitaxial film 5 corresponding to the first main surface 2 and the distal end of the epitaxial crown 7.

### Effect

Since the SiC substrate 1 according to the embodiment 5 includes the second main surface 3, when the SiC epitaxial film 5 having the thickness of approximately 30 μm is epitaxially grown on the SiC substrate 1, the epitaxial crown 7 having the height H7 of 15 μm or less is formed on the SiC epitaxial film 5. That is to say, according to the embodiment 5, the height of the epitaxial crown 7 formed on the SiC epitaxial film 5 can be suppressed.

### Embodiment 6

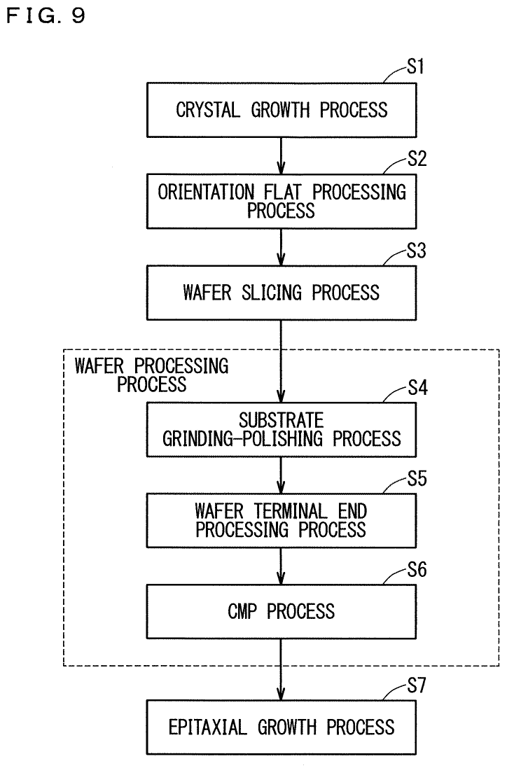

FIG. 9 is a flow chart illustrating a manufacturing process of the SiC substrate 1 according to an embodiment 6.

An SiC single crystal is grown to manufacture ingot in a crystal growth process in Step S1.

An orientation flat is formed on the SiC single crystal ingot in an orientation flat processing process in Step S2. A notch may be formed in the ingot in place of the orientation flat.

The ingot is sliced to form the SiC substrate 1 in a wafer slicing process in Step S3.

In a substrate grinding-polishing process in Step S4, the front surface of the SiC substrate 1 obtained by slicing the ingot is ground or polished. Specifically, the SiC substrate 1 is ground or polished to have a desired thickness.

The end surface processing portion 4 is formed in the terminal end portion of the SiC substrate 1 in a wafer terminal processing process in Step S5.

In a chemical mechanical polishing (CMP) process in Step S6, the front surface of the SiC substrate 1 is flattened.

In an epitaxial growth process in Step S7, an epitaxial growth is performed on the SiC substrate 1 to form the SiC epitaxial film 5.

Step S4 to Step S6 described above are a wafer processing process for processing the SiC substrate 1. In the wafer processing process, the first main surface 2 (Step S6), the second main surface 3, and the end surface processing portion 4 (Step S5) are formed. It is sufficient that the second main surface 3 is formed between Step S4 and Step S5 or between Step S5 and Step S6.

### Effect

Since the first main surface 2, the second main surface 3, and the end surface processing portion 4 are formed in the wafer processing process to control the front surface shape of the SiC substrate 1, the height of the epitaxial crown 7 formed on the SiC epitaxial film 5 after the epitaxial growth from the front surface of the SiC substrate 1 (the first main surface 2) can be suppressed.

Each embodiment can be arbitrarily combined, or each embodiment can be appropriately varied or omitted within the scope of the present disclosure.

### Appendix

The aspects of the present disclosure are collectively described hereinafter as appendixes.

### (Appendix 1)

A semiconductor substrate, comprising:
an effective region as a region in which a semiconductor chip is formed and including a first main surface;
an ineffective region located on an outer surrounding of the first main surface and including a second main surface having a surface shape different from the first main surface; and
an end surface processing portion located on an outer surrounding of the second main surface and included in the ineffective region, wherein
a surface height of the second main surface is lower than a surface height of the first main surface.

### (Appendix 2)

The semiconductor substrate according to Appendix 1, wherein
the semiconductor chip includes SiC.

### (Appendix 3)

The semiconductor substrate according to Appendix 1 or 2, wherein
the second main surface has a tapered shape, a stepwise shape, or a convex-concave shape.

### (Appendix 4)

The semiconductor substrate according to any one of Appendixes 1 to 3, wherein
a difference between a surface height of the first main surface and a surface height of the second main surface is 4.5% to 21.5% of a thickness of the semiconductor substrate.

### (Appendix 5)

The semiconductor substrate according to any one of Appendixes 1 to 4, wherein
a boundary between the first main surface and the second main surface, a boundary between the second main surface and the end surface processing portion, and a boundary between the end surface processing portion and a side surface of the semiconductor substrate are chamfered.

### (Appendix 6)

A semiconductor epitaxial wafer, comprising:
the semiconductor substrate according to any one of Appendixes 1 to 5; and
a semiconductor epitaxial film provided on the semiconductor substrate, wherein
a thickness of the semiconductor epitaxial film is equal to or larger than 30 μm, and
a height of a protruding portion formed on a surface of the semiconductor epitaxial film corresponding to the second main surface is 4.5% of a thickness of the semiconductor substrate.

### (Appendix 7)

A semiconductor epitaxial wafer, comprising:
the semiconductor substrate according to any one of Appendixes 1 to 5; and
a semiconductor epitaxial film provided on the semiconductor substrate, wherein
a height of a protruding portion formed on the surface of the semiconductor epitaxial film corresponding to the second main surface is 15 μm or less from the surface of the semiconductor epitaxial film corresponding to the first main surface, and
a position of a bottom portion of the protruding portion is lower than the surface of the semiconductor epitaxial film corresponding to the first main surface.

### (Appendix 8)

A method of manufacturing the semiconductor substrate according to any one of Appendixes 1 to 5, comprising the steps of:
(a) forming an orientation flat or a notch in an ingot of single crystal;
(b) slicing the ingot and forming a semiconductor substrate;
(c) grinding or polishing a surface or a terminal end of the semiconductor substrate; and
(d) performing epitaxial growth on the semiconductor substrate and forming a semiconductor epitaxial film, wherein
the step (c) includes a step of forming the first main surface, the second main surface, and the end surface processing portion.

While the disclosure has been shown and described in detail, the foregoing description is in all aspects illustrative and not restrictive. It is therefore understood that numerous modifications and variations can be devised.

What is claimed is:

1. A semiconductor substrate, comprising:
an effective region as a region in which a semiconductor chip is formed and including a first main surface;
an ineffective region located on an outer surrounding of the first main surface and including a second main surface having a surface shape different from the first main surface; and
an end surface processing portion located on an outer surrounding of the second main surface and included in the ineffective region, wherein
a surface height of the second main surface is lower than a surface height of the first main surface.

2. The semiconductor substrate according to claim 1, wherein
the semiconductor chip includes SiC.

3. The semiconductor substrate according to claim 1, wherein
the second main surface has a tapered shape, a stepwise shape, or a convex-concave shape.

4. The semiconductor substrate according to claim 1, wherein
a difference between a surface height of the first main surface and a surface height of the second main surface is 4.5% to 21.5% of a thickness of the semiconductor substrate.

5. The semiconductor substrate according to claim 1, wherein
a boundary between the first main surface and the second main surface, a boundary between the second main surface and the end surface processing portion, and a boundary between the end surface processing portion and a side surface of the semiconductor substrate are chamfered.

6. A semiconductor epitaxial wafer, comprising:
the semiconductor substrate according to claim 1; and
a semiconductor epitaxial film provided on the semiconductor substrate, wherein
a thickness of the semiconductor epitaxial film is equal to or larger than 30 μm, and
a height of a protruding portion formed on a surface of the semiconductor epitaxial film corresponding to the second main surface is 4.5% of a thickness of the semiconductor substrate.

7. A semiconductor epitaxial wafer, comprising:
the semiconductor substrate according to claim 1; and
a semiconductor epitaxial film provided on the semiconductor substrate, wherein
a height of a protruding portion formed on the surface of the semiconductor epitaxial film corresponding to the second main surface is 15 μm or less from the surface of the semiconductor epitaxial film corresponding to the first main surface, and
a position of a bottom portion of the protruding portion is lower than the surface of the semiconductor epitaxial film corresponding to the first main surface.

8. A method of manufacturing the semiconductor substrate according to claim 1, comprising the steps of:
(a) forming an orientation flat or a notch in an ingot of single crystal;
(b) slicing the ingot and forming a semiconductor substrate;
(c) grinding or polishing a surface or a terminal end of the semiconductor substrate; and
(d) performing epitaxial growth on the semiconductor substrate and forming a semiconductor epitaxial film, wherein
the step (c) includes a step of forming the first main surface, the second main surface, and the end surface processing portion.
